(19) United States
(12) Patent Application Publication
(10) Pub. No.: US 2014/0042586 A1
(43) Pub. Date: Feb. 13, 2014

(54) SILICON SUBSTRATE AND METHOD OF FABRICATING THE SAME

(71) Applicant: SAMSUNG ELECTRO-MECHANICS CO., LTD., Suwon (KR)

(72) Inventors: Hyun Kee LEE, Suwon (KR); Sung Min CHO, Suwon (KR)

(73) Assignee: SAMSUNG ELECTRO-MECHANICS CO., LTD., Suwon (KR)

(21) Appl. No.: 13/673,115

(22) Filed: Nov. 9, 2012

(30) Foreign Application Priority Data
Aug. 10, 2012 (KR) 10-2012-0087941

(51) Int. Cl. H01L 29/16; H01L 21/762

(52) U.S. Cl. 257/506; 257/622; 438/456; 257/E29.082; 257/E21.567

(57) ABSTRACT

There are provided a silicon substrate and a method of fabricating the same, the silicon substrate including: first and second silicon substrates having corresponding bonding surfaces; a silicon oxide film formed between the first and second silicon substrates and having at least one trench communicating with the outside; and a hermetic portion formed on an end portion of the trench according to oxidation of the silicon oxide film.

### CROSS-REFERENCE TO RELATED APPLICATIONS

This application claims the priority of Korean Patent Application No. 10-2012-0087941 filed on Aug. 10, 2012, in the Korean Intellectual Property Office, the disclosure of which is incorporated herein by reference.

### BACKGROUND OF THE INVENTION

1. Field of the Invention

The present invention relates to a silicon substrate and a method of fabricating the same.

2. Description of the Related Art

A silicon substrate, generally known as wafer, is used in manufacturing various semiconductor devices.

Namely, various semiconductor devices are formed on a silicon substrate through a micromachining process such as forming a layer of a certain material on a silicon substrate or etching a surface of a silicon substrate, or the like.

In the semiconductor device fabrication process, in some cases, a semiconductor device having a stereoscopic structure is formed, or two silicon substrates are bonded to be used for a wafer-level package of a semiconductor device, or the like.

In this case, the method of bonding two silicon substrates may include silicon direct bonding, anodic bonding, and the like, without a medium layer, and metal bonding, glass frit bonding, polymer bonding, and the like, with a medium layer.

Among them, generally used silicon direct bonding is a method of bonding silicon substrates having surfaces of Si, SiO₂, or the like. In this method, both surfaces of the silicon substrates are subjected to hydrophilic processing to form OH groups, provisionally bonded through OH group coupling, and then, finally bonded in a high temperature heat treatment.

Here, as for the process of provisional bonding, two silicon substrates are aligned and single regions of the silicon substrates are brought into contact. Then, OH bonding first takes place from the contact regions and bonding waves, starting from the coupled regions, are spontaneously propagated to bond the surfaces of the silicon substrates.

Here, when bonding waves are generated in several regions of the silicon substrates, air may be trapped in spots in which bonding waves meet to thereby generate voids, rather than allowing for uniform bonding, and such voids may result in chip defects in regions in which voids are generated according to a size thereof and a generation of cracks due to thermal expansion during a follow-up process.

Thus, bonding waves are required to have a single structure, rather than a complex structure, and in order to use single bonding waves in silicon direct bonding, central portions or corner portions of silicon substrates should be brought into mutual contact to allow bonding to be expanded.

However, in the case that silicon substrates are bent due to warpage, or the like, several portions of the silicon substrates may come into contact with each other during an initial contacting process, potentially generating complex bonding waves.

In an effort to solve this problem, a method of forming vent holes in several portions of the silicon substrates to allow air generated as bonding waves meet to leak out, rather than being trapped, was disclosed.

This technique, however, has a problem in that a wet process among follow-up processes cannot be performed because holes are formed in silicon substrates after bonding of the silicon substrates is completed.

Namely, a solution infiltrates through the vent holes during the wet process to contaminate the interior of the device, so the technique can only be limitedly applied to products made without a follow-up process or made through only a dry process without a wet process in follow-up processes in case of silicon direct bonding.

Patent Document 1 relates to a silicon direct bonding method which, however, does not disclose hermetically closing an end portion of a trench and performing a wet process among follow-up processes.

### RELATED ART DOCUMENT

(Patent Document 1) Korean Patent Publication No. 10-0571848

### SUMMARY OF THE INVENTION

An aspect of the present invention provides a novel method for performing a follow-up wet process, or the like, after bonding, while preventing a generation of voids within silicon substrates when two silicon substrates are bonded.

According to an aspect of the present invention, there is provided a silicon substrate including: first and second silicon substrates having corresponding bonding surfaces; a silicon oxide film formed between the first and second silicon substrates and having at least one trench communicating with the outside; and a hermetic portion formed on an end portion of the trench according to oxidation of the silicon oxide film.

According to another aspect of the present invention, there is provided a silicon substrate including: first and second silicon substrates having corresponding bonding surfaces; at least one trench formed in at least one of the bonding surfaces of the first and second silicon substrates to communicate with the outside; and a hermetic portion formed on an end portion of the trench according to oxidation of the bonding surface of the first or second silicon substrate.

The trench may extend to an edge portion of the silicon oxide film in a horizontal direction.

The silicon substrate may further include a through hole formed to be perpendicular with respect to at least one of the bonding surfaces of the first and second silicon substrates, from the trench.

The trench may include a plurality of first trenches formed to be spaced apart from each other in a first direction and a plurality of second trenches formed to be spaced apart from each other in a second direction perpendicular with respect to the first direction.

According to another aspect of the present invention, there is provided a method of fabricating a silicon substrate, including: preparing first and second silicon substrates having corresponding bonding surfaces; forming a silicon oxide film on the bonding surface of the first silicon substrate; forming a trench communicating with the outside, in the silicon oxide film; tightly attaching the bonding surface of the second silicon substrate onto the silicon oxide film having the trench formed therein, and performing a thermal treatment thereon to bond the first and second silicon substrates; and oxidizing the bonded first and second silicon substrates and allowing the silicon oxide film to be grown to seal an end portion of the trench.

According to another aspect of the present invention, there is provided a method of fabricating a silicon substrate, including: preparing first and second silicon substrates having corresponding bonding surfaces; forming a trench communicating with the outside in the bonding surface of the first silicon substrate; tightly attaching the bonding surfaces of the first and second silicon substrates and performing a thermal treatment thereon to bond the first and second silicon substrates; and oxidizing at least one of the bonding surfaces of the first and second silicon substrates and allowing a silicon oxide film to be grown to seal an end portion of the trench.

The trench may extend to an edge portion of the silicon oxide film in a horizontal direction.

The method may further include forming a through hole to be perpendicular with respect to at least one of the bonding surfaces of the first and second silicon substrates, from the trench.

The method may further include: cleaning the bonded first and second silicon substrates in a wet manner, after the sealing of the end portion of the trench.

The trench may be formed along at least a part of a plurality of dicing lines.

The plurality of dicing lines may include a plurality of first lines formed to be spaced apart from each other in a first direction and a plurality of second lines formed to be spaced apart in a second direction perpendicular with respect to the first direction, and the trench may include a plurality of trenches formed along one of the plurality of first and second lines. The plurality of dicing lines include a plurality of first lines formed to be spaced apart from each other in a first direction and a plurality of second lines formed to be spaced apart in a second direction perpendicular with respect to the first direction, and the trench may include a plurality of trenches formed along both of the plurality of first and second lines.

The method further include forming a through hole to be perpendicular with respect to the bonding surface of the first or second silicon substrate, from a trench among the trenches, in which the first and second lines intersect.

The trench may be formed by etching the bonding surface of the first silicon substrate to a certain depth.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view of a silicon substrate according to an embodiment of the present invention;

FIG. 2 is an enlarged view of portion A of FIG. 1;

FIG. 3 is a plan view of FIG. 1;

FIG. 4 is a perspective view of a silicon substrate according to another embodiment of the present invention;

FIG. 5 is an enlarged view of portion B of FIG. 4;

FIG. 6 is a cross-sectional view of FIG. 4;

FIG. 7 is a cross-sectional view of a silicon substrate according to another embodiment of the present invention; and

FIGS. 8A to 8F are cross-sectional views showing a method of fabricating a silicon substrate according to an embodiment of the present invention;

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like elements.

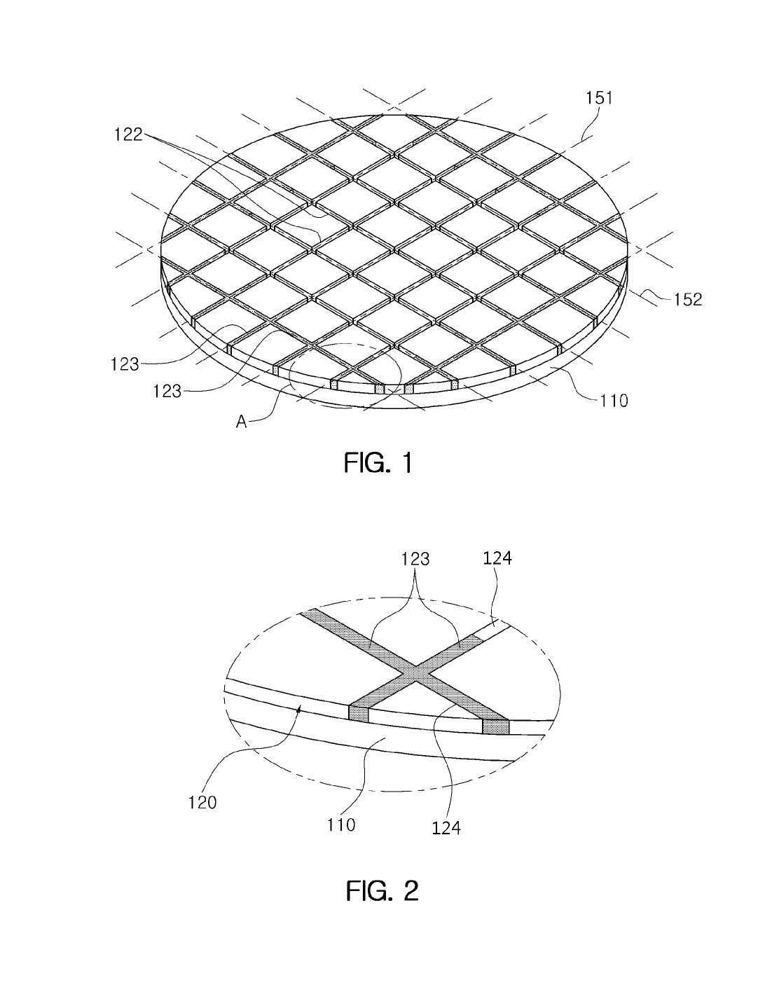

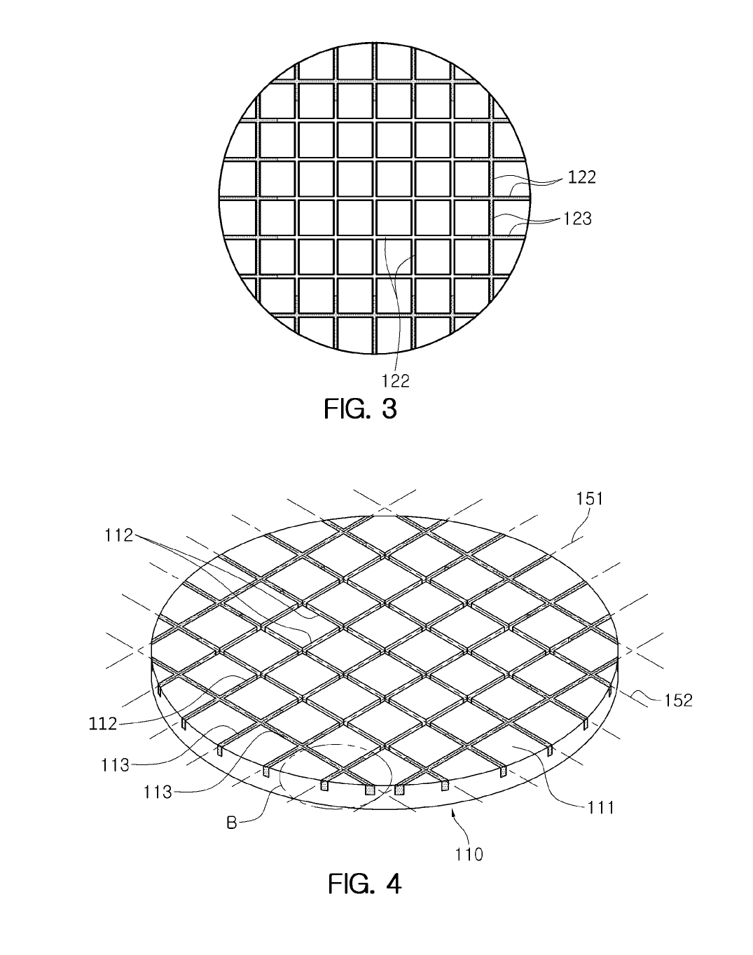

Referring to FIGS. 1 through 3, a silicon substrate according to the present embodiment includes first and second silicon substrates 110 and 130 having corresponding bonding surfaces 111 and 131, a silicon oxide film 120 formed between the first and second silicon substrates 110 and 130 and having at least one trench 122 communicating with the outside, and a hermetic portion 123 formed on an end portion of the trench 122 according to oxidation of the silicon oxide film 120.

The first and second silicon substrates 110 and 130 may be silicon wafers commonly used for fabricating a semiconductor device.

The trench 122 may extend to an edge portion of the silicon oxide film 120 in a horizontal direction.

Also, the trench 122 may include a plurality of trenches formed to be spaced apart from each other in a first direction and a plurality of second trenches spaced apart from each other in a second direction perpendicular in relation to the first direction.

Here, the trench 122 may be formed to correspond to an unpatterned region of the first and second silicon substrates 110 and 130.

The trench 122 may discharge air trapped in the interior due to a thermal treatment at the time of bonding the second silicon substrate to the first silicon substrate, to the outside, to thereby significantly reduce a generation of voids.

Also, the hermetic portion formed on the end portion of the trench 122 according to oxidation of the silicon oxide film 120 may block moisture from being introduced into the bonded first and second silicon substrates 110 and 130 and thus allow for a follow-up wet process such as wet cleaning, or the like.

Reference numerals 151 and 152 denote dicing lines. A dicing process will be described in detail hereinafter in a fabrication method of a silicon substrate.

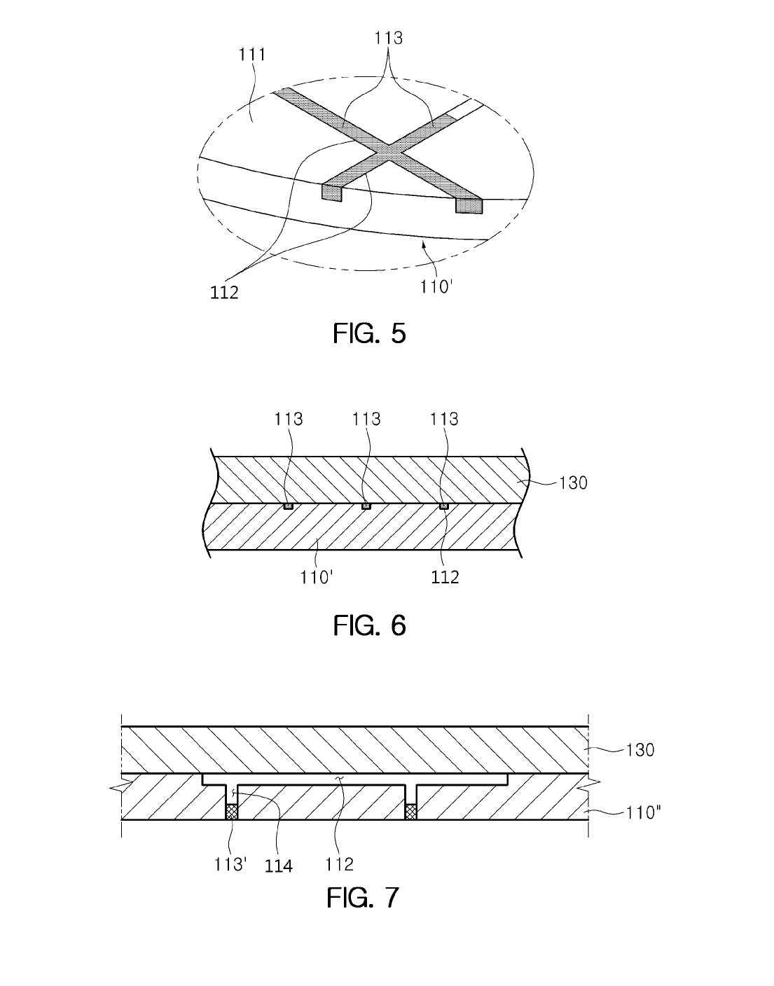

FIGS. 4 through 6 illustrate a silicon substrate according to another embodiment of the present invention.

Referring to FIGS. 4 through 6, in the silicon substrate according to another embodiment of the present invention, the silicon oxide film in the above-mentioned embodiment is omitted, and a trench 112 is formed in a bonding surface of a first silicon substrate 110′.

However, the present invention is not limited thereto and the trench 112 may be formed in a bonding surface of the second silicon substrate 130. Also, a hermetic portion 113 may be formed on an end portion of the trench 112 according to oxidation of the bonding surfaces 111 and 131 of the first and second silicon substrates 110′ and 130.

Hereinafter, a formation structure of the trench 112 according to another embodiment of the present invention is the same as that of the above-mentioned embodiment, so a detailed description thereof will be omitted in order to avoid repetition.

FIG. 7 illustrates a silicon substrate according to another embodiment of the present invention.

Referring to FIG. 7, in the silicon substrate according to another embodiment of the present invention, the trench 112 is formed in a bonding surface of a first silicon substrate 110″ in a horizontal direction, a through hole 114 is further formed from the trench 112 to a lower surface of the first silicon substrate 110″ in a direction perpendicular with respect to the bonding surface of the first silicon substrate 110″, and a hermetic portion 113′ is formed on an end portion of the through hole 114.

However, the present invention is not limited thereto. For example, the through hole 114 may be formed to be connected to an upper surface of the second silicon substrate 130 in a direction perpendicular with respect to the bonding surface of the second silicon substrate 130.

Meanwhile, the silicon oxide film is omitted in the present embodiment, and even in case of an embodiment including a silicon oxide film, a through hole may be formed to penetrate the silicon substrate perpendicularly with respect to one bonding surface of the first or second silicon substrate 110″ or 130 in a similar manner as that of the present embodiment.

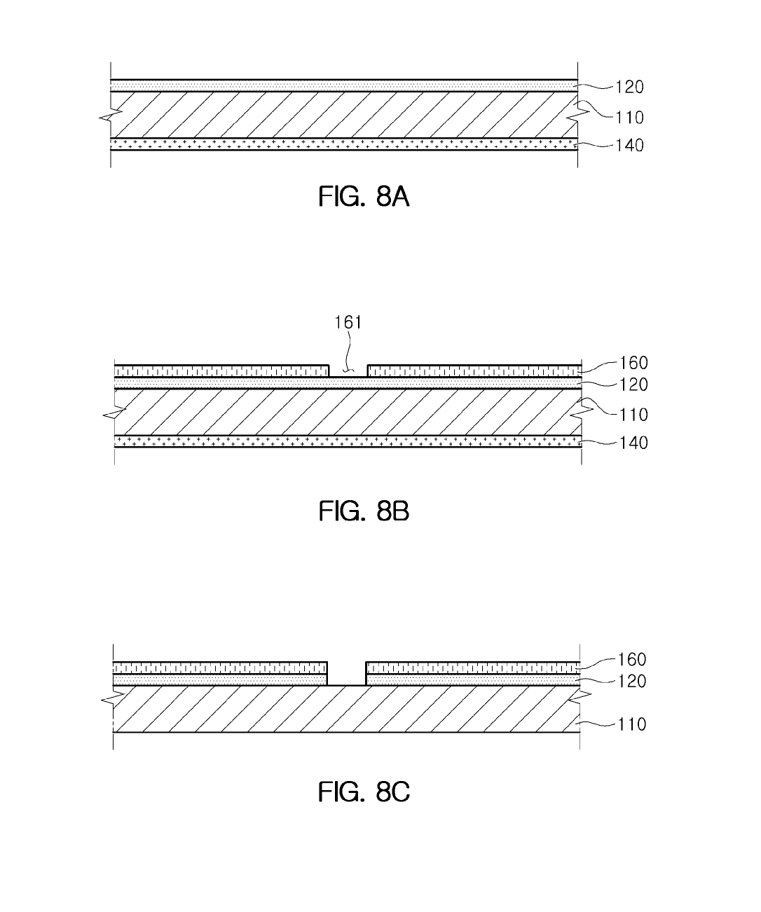

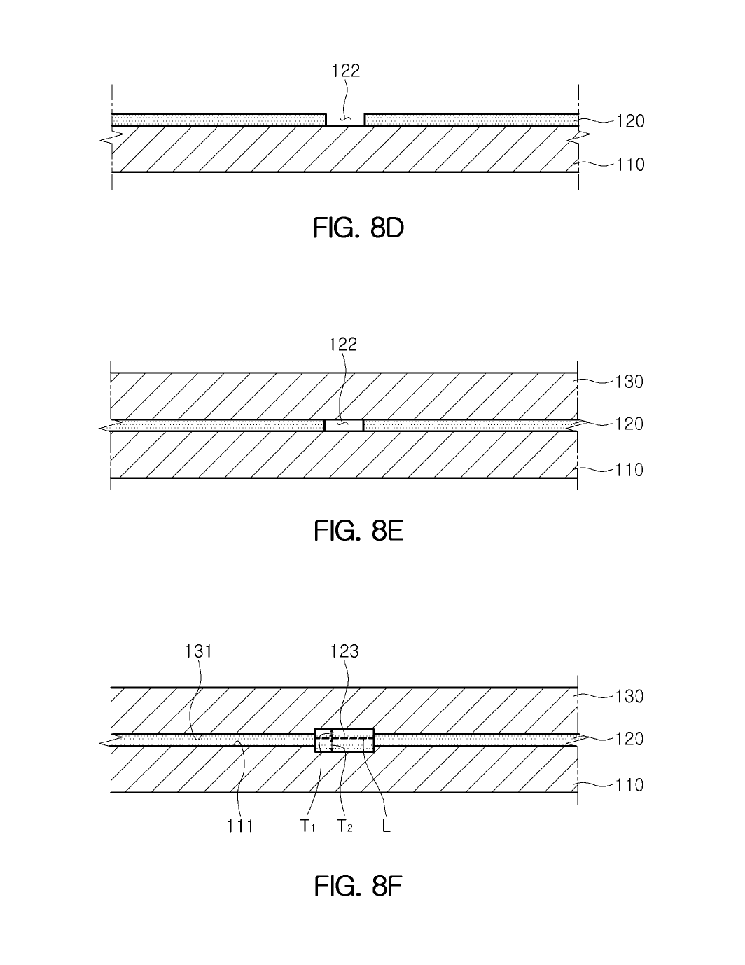

A method of fabricating a silicon substrate according to an embodiment of the present invention will be described with reference to FIGS. 8A through 8F.

First, the first and second silicon substrates 110 and 130 having corresponding bonding surfaces 111 and 131 are prepared.

The first and second silicon substrates 110 and 130 may be silicon wafers commonly used for fabricating a semiconductor device.

Next, the bonding surface 111 of the first silicon substrate 110 may be oxidized to form the silicon oxide film 120.

Thereafter, a photoresist 160 is applied to the silicon oxide film 120 and subsequently patterned to have a certain pattern 161 through an exposure and development process, such that a portion of the silicon oxide film 120 may be exposed.

Thereafter, the exposed silicon oxide film 120 is etched by using the photoresist 160 as an etching mask to form the trench 122. Here, the silicon oxide film 120 may be etched through dry etching or wet etching. Subsequently, when the photoresist 160 is stripped, only the silicon oxide film 120 having the trench 122 of a certain depth may remain on the bonding surface 111 of the first silicon substrate 110.

Thereafter, the trench 122 may be formed to communicate with the outside, through the etching of the silicon oxide film 120. The trench 122 may be extend to an edge portion of the silicon oxide film 120 in a horizontal direction, and accordingly, air trapped between the first and second silicon substrates 110 and 130 that are bonded to each other may be discharged to the outside, thus significantly reducing a generation of voids.

The trench 122 may be formed to penetrate the entire thickness of the silicon oxide film 120, but if necessary, the trench 122 maybe formed only in a portion of the entire thickness of the silicon oxide film 120.

The trench 122 may be formed along at least a part of the plurality of dicing lines 151 and 152 so as not to affect a semiconductor device formed in the first and second silicon substrates 110 and 130.

Dicing refers to cutting the first and second silicon substrates 110 and 130 to be separated into a plurality of semiconductor devices after the semiconductor devices are formed on the first and second silicon substrates 110 and 130.

Here, the dicing lines 151 and 152 may include a plurality of first lines 151 formed to be spaced apart from each other in a first direction, and a plurality of second lines 152 formed to be spaced apart from each other in a second direction perpendicular with respect to the first direction.

A plurality of trenches 122 may be formed along one of the first and second lines 151 and 152, or the plurality of trenches 122 may be formed along both of the first and second lines 151 and 152.

Meanwhile, the process of forming the silicon oxide film 120 may be omitted as necessary, and in this case, a trench may be formed by etching the bonding surface 111 of the first silicon substrate 110 by a certain depth, and a follow-up process as described hereinafter may be subsequently performed in a manner similar to that of the present embodiment.

Also, a through hole may be formed to be perpendicular with respect to at least one of the bonding surfaces of the first and second silicon substrates 110 and 130, from the trench 122. In this case, since the through hole serves as a vent hole, an end portion of the trench 122 may not be required to extend to an edge portion of the silicon oxide film.

Next, the bonding surface 131 of the second silicon substrate 130 is tightly attached to the silicon oxide film 120 and thermally treated to be bonded.

When the first and second silicon substrates 130 are tightly attached, they are provisionally bonded by van der Waals force between ions and molecules, and in this state, the provisionally bonded first and second silicon substrates 110 and 130 are thermally treated at a high temperature. Then, the first and second silicon substrates 110 and 130 are firmly bonded due to mutual diffusion of atoms between the first and second silicon substrates 110 and 130.

Here, gas may be generated by the ions and molecules existing between the first and second silicon substrates 110 and 130 during the thermal treatment, but the gas may be introduced into the trench 122 adjacent thereto and smoothly discharged to the outside of the first and second silicon substrates 110 and 130 through the trench 122.

Thereafter, the silicon oxide film 120 is oxidized to seal an end portion of the trench 122, thus completing the silicon substrate.

Namely, when oxidation is performed after the second silicon substrate 130 is bonded to the silicon oxide film 120 having the trench 122, an edge portion of the silicon oxide film 120 is exposed to a reactive gas and an end portion of the trench 122 is oxidized, such that a SiO₂ film having a thickness T1 of about 55% in an upward direction and a thickness T2 of about 45% in a downward direction, centered on the surface of the silicon oxide film 120 may be grown.

For example, in the event in which a gas discharge hole having a depth of 1 μm is formed, when an oxidation process is performed such that a film having a thickness of 1 μm is formed, a film having a thickness of 0.55 μm and a film having a thickness of 0.45 μm are grown on the bonding surfaces of the first and second silicon substrates. The both oxide films are added, such that an end portion of the trench 122 may be blocked by the hermetic portion 123 having the thickness of 1 μm.

Thereafter, wet cleaning may further be performed on the bonded first and second silicon substrates 110 and 130. Namely, since the hermetic portion is formed on the end portion of the trench 122, even in the case that a wet process is performed, moisture may not remain within the silicon substrates.

As set forth above, according to embodiments of the invention, since a gas generated during a thermal treatment process is discharged through the trench, a generation of voids in the bonding surface of the silicon substrate can be prevented, and thus, a production yield of chips can be improved. In addition, since cracks due to voids are prevented, defects in silicon substrate can be prevented, thus enhancing a production yield.

In addition, since an end portion of the trench is sealed after first and second silicon substrates are bonded, a follow-up wet process such as wet cleaning, or the like, can be performed, whereby the silicon substrate according to the embodiments of the present invention can be utilized in various fields of application.

While the present invention has been shown and described in connection with the embodiments, it will be apparent to those skilled in the art that modifications and variations can be made without departing from the spirit and scope of the invention as defined by the appended claims.

What is claimed is:

1. A silicon substrate comprising:
first and second silicon substrates having corresponding bonding surfaces;
a silicon oxide film formed between the first and second silicon substrates and having at least one trench communicating with the outside; and
a hermetic portion formed on an end portion of the trench according to oxidation of the silicon oxide film.

2. The silicon substrate of claim 1, wherein the trench extends to an edge portion of the silicon oxide film in a horizontal direction.

3. The silicon substrate of claim 1, further comprising a through hole formed to be perpendicular with respect to at least one of the bonding surfaces of the first and second silicon substrates, from the trench.

4. The silicon substrate of claim 1, wherein the trench includes a plurality of first trenches formed to be spaced apart from each other in a first direction and a plurality of second trenches formed to be spaced apart from each other in a second direction perpendicular with respect to the first direction.

5. A silicon substrate comprising:
first and second silicon substrates having corresponding bonding surfaces;
at least one trench formed in at least one of the bonding surfaces of the first and second silicon substrates to communicate with the outside; and
a hermetic portion formed on an end portion of the trench according to oxidation of the bonding surface of the first or second silicon substrate.

6. The silicon substrate of claim 5, wherein the trench extends to an edge portion of at least one of the first and second silicon substrates in a horizontal direction.

7. The silicon substrate of claim 5, further comprising a through hole formed to be perpendicular with respect to at least one of the bonding surfaces of the first and second silicon substrates, from the trench.

8. The silicon substrate of claim 5, wherein the trench includes a plurality of first trenches formed to be spaced apart from each other in a first direction and a plurality of second trenches formed to be spaced apart from each other in a second direction perpendicular with respect to the first direction.

9. A method of fabricating a silicon substrate, the method comprising:
preparing first and second silicon substrates having corresponding bonding surfaces;
forming a silicon oxide film on the bonding surface of the first silicon substrate;
forming a trench communicating with the outside, in the silicon oxide film;
tightly attaching the bonding surface of the second silicon substrate onto the silicon oxide film having the trench formed therein, and performing a thermal treatment thereon to bond the first and second silicon substrates; and
oxidizing the bonded first and second silicon substrates and allowing the silicon oxide film to be grown to seal an end portion of the trench.

10. The method of claim 9, wherein the trench extends to an edge portion of the silicon oxide film in a horizontal direction.

11. The method of claim 9, further comprising forming a through hole to be perpendicular with respect to at least one of the bonding surfaces of the first and second silicon substrates, from the trench.

12. The method of claim 9, further comprising cleaning the bonded first and second silicon substrates in a wet manner, after the sealing of the end portion of the trench.

13. The method of claim 9, wherein the trench is formed along at least a part of a plurality of dicing lines.

14. The method of claim 13, wherein the plurality of dicing lines include a plurality of first lines formed to be spaced apart from each other in a first direction and a plurality of second lines formed to be spaced apart in a second direction perpendicular with respect to the first direction, and the trench includes a plurality of trenches formed along one of the plurality of first and second lines.

15. The method of claim 13, wherein the plurality of dicing lines include a plurality of first lines formed to be spaced apart from each other in a first direction and a plurality of second lines formed to be spaced apart in a second direction perpendicular with respect to the first direction, and the trench includes a plurality of trenches formed along both of the plurality of the first and second lines.

16. The method of claim 15, further comprising forming a through hole to be perpendicular with respect to the bonding surface of the first or second silicon substrate, from a trench among the trenches, in which the first and second lines intersect.

17. A method of fabricating a silicon substrate, the method comprising:
preparing first and second silicon substrates having corresponding bonding surfaces;
forming a trench communicating with the outside in the bonding surface of the first silicon substrate;
tightly attaching the bonding surfaces of the first and second silicon substrates and performing a thermal treatment thereon to bond the first and second silicon substrates; and
oxidizing at least one of the bonding surfaces of the first and second silicon substrates and allowing a silicon oxide film to be grown to seal an end portion of the trench.

18. The method of claim 17, wherein the trench extends to an edge portion of the silicon oxide film in a horizontal direction.

19. The method of claim 17, further comprising forming a through hole to be perpendicular with respect to at least one of the bonding surfaces of the first and second silicon substrates, from the trench.

20. The method of claim 17, further comprising cleaning the bonded first and second silicon substrates in a wet manner, after the sealing of the end portion of the trench.

21. The method of claim 17, wherein the trench is formed along at least a part of a plurality of dicing lines.

22. The method of claim 21, wherein the plurality of dicing lines include a plurality of first lines formed to be spaced apart from each other in a first direction and a plurality of second lines formed to be spaced apart in a second direction perpendicular with respect to the first direction, and the trench includes a plurality of trenches formed along one of the plurality of first and second lines.

23. The method of claim 21, wherein the plurality of dicing lines include a plurality of first lines formed to be spaced apart from each other in a first direction and a plurality of second lines formed to be spaced apart in a second direction perpendicular with respect to the first direction, and the trench includes a plurality of trenches formed along both of the plurality of first and second lines.

24. The method of claim 23, further comprising forming a through hole to be perpendicular with respect to the bonding surface of the first or second silicon substrate, from a trench among the trenches, in which the first and second lines intersect.

25. The method of claim 17, wherein the trench is formed by etching the bonding surface of the first silicon substrate by a certain depth.
